(19) United States
(12) Patent Application Publication
(10) Pub. No.: US 2020/0020562 A1
(43) Pub. Date: Jan. 16, 2020

(54) VACUUM CHUCK FOR BONDING SUBSTRATES, APPARATUS FOR BONDING SUBSTRATES INCLUDING THE SAME, AND METHOD OF BONDING SUBSTRATES USING THE SAME

(71) Applicant: SAMSUNG ELECTRONICS CO., LTD., Suwon-si (KR)

(72) Inventors: Ki-Ju SOHN, Gunpo-si (KR); Sung-Hyup KIM, Hwaseong-si (KR)

(21) Appl. No.: 16/245,437

(22) Filed: Jan. 11, 2019

(30) Foreign Application Priority Data
Jul. 16, 2018 (KR) 10-2018-0082137

(51) Int. Cl. H01L 21/683; H01L 21/67; H01L 21/687; H01L 23/00

(52) U.S. Cl. CPC H01L 21/6838; H01L 21/67109; H01L 21/68785; H01L 24/01; H01L 21/67092; H01L 24/74; H01L 21/67248

(57) ABSTRACT

A vacuum chuck for bonding substrates includes a chucking plate including vacuum holes to hold the substrate, partitions arranged in the chucking plate, the partitions dividing the chucking plate into regions, and a temperature control member in each one of the regions, the temperature control member to independently control temperature in each of the regions to selectively expand or contract portions of the substrate in contact with each of the regions.

### CROSS-REFERENCE TO RELATED APPLICATION

Korean Patent Application No. 2018-0082137, filed on Jul. 16, 2018, in the Korean Intellectual Property Office (KIPO), and entitled: “Vacuum Chuck for Bonding Substrates, Apparatus for Bonding Substrates Including the Same, and Method of Bonding Substrates Using the Same,” is incorporated by reference herein in its entirety.

### BACKGROUND

### 1. Field

Example embodiments relate to a vacuum chuck for bonding substrates, an apparatus for bonding substrates including the same, and a method of bonding substrates using the same. More particularly, example embodiments relate to a vacuum chuck used for bonding semiconductor substrates, an apparatus for bonding semiconductor substrates including the vacuum chuck, and a method of bonding semiconductor substrates using the vacuum chuck.

### 2. Description of the Related Art

In order to increase an integration degree of a semiconductor device, an upper semiconductor substrate and a lower semiconductor substrate including a plurality of semiconductor chips may be stacked using a bonding apparatus. Contacts of the stacked upper and lower semiconductor substrates may be electrically connected with each other. The bonding apparatus may include a lower vacuum chuck for holding the lower semiconductor substrate using vacuum, an upper vacuum chuck for holding the upper semiconductor substrate using vacuum, and a bonding pin for pressurizing the upper semiconductor substrate toward the lower semiconductor substrate.

### SUMMARY

According to example embodiments, there may be provided a vacuum chuck for bonding substrates. The vacuum chuck may include a chucking plate, a plurality of partitions and a temperature control member. The chucking plate may include a plurality of vacuum holes for holding the substrate. The partitions may be arranged in the chucking plate to divide the chucking plate into a plurality of regions. The temperature control member may be arranged in each of the regions to independently control temperatures of the regions, thereby selectively expanding or contracting portions of the substrate making contact with the regions.

According to example embodiments, there may be provided an apparatus for bonding substrates. The apparatus may include an upper vacuum chuck, a lower vacuum chuck and a bonding pin. The upper vacuum chuck may include an upper vacuum hole for holding an upper substrate. The lower vacuum chuck may include a chucking plate, a plurality of partitions and a temperature control member. The chucking plate may include a plurality of lower vacuum holes for holding a lower substrate. The partitions may be arranged in the chucking plate to divide the chucking plate into a plurality of regions. The temperature control member may be arranged in each of the regions to independently control temperatures of the regions, thereby selectively expanding or contracting portions of the lower substrate making contact with the regions. The bonding pin may be arranged over the upper vacuum chuck to pressurize the upper substrate toward the lower substrate.

According to example embodiments, there may be provided a method of bonding substrates. In the method of bonding the substrates, an upper reference substrate and a lower reference substrate may be bonded with each other using an upper vacuum chuck and a lower vacuum chuck. Reference overlays between upper reference contacts in the upper reference substrate and lower reference contacts in the lower reference substrate may be measured. The upper vacuum chuck may hold an upper substrate. The lower vacuum chuck may hold a lower substrate. Regions in the lower vacuum chuck may be selectively heated or cooled in accordance with the reference overlays to selectively expand or contract portions of the lower substrate corresponding to the regions, thereby aligning the upper contacts and the lower contacts with each other. The upper substrate and the lower substrate may then be bonded with each other.

### BRIEF DESCRIPTION OF THE DRAWINGS

Features will become apparent to those of skill in the art by describing in detail exemplary embodiments with reference to the attached drawings, in which:

FIG. 1 illustrates a schematic cross-sectional view of an apparatus for bonding substrates in accordance with example embodiments;

FIG. 2 illustrates a bottom view of an upper vacuum chuck of the apparatus in FIG. 1;

FIG. 3 illustrates a plan view of a lower vacuum chuck of the apparatus in FIG. 1;

FIG. 4 illustrates a cross-sectional view of the lower vacuum chuck in FIG. 3;

FIGS. 5 and 6 illustrate cross-sectional views of contacts of bonded upper and lower substrates;

FIG. 7 illustrates a cross-sectional view of a lower vacuum chuck of a bonding apparatus in accordance with example embodiments;

FIG. 8 illustrates a block diagram of a Peltier element of the vacuum chuck in FIG. 7;

FIG. 9 illustrates a cross-sectional view of a lower vacuum chuck of a bonding apparatus in accordance with example embodiments; and

FIGS. 10 to 19 illustrate cross-sectional views of stages in a method of bonding substrates using the apparatus in FIG. 1.

### DETAILED DESCRIPTION

Hereinafter, example embodiments will be explained in detail with reference to the accompanying drawings.

Apparatus for Bonding Substrates

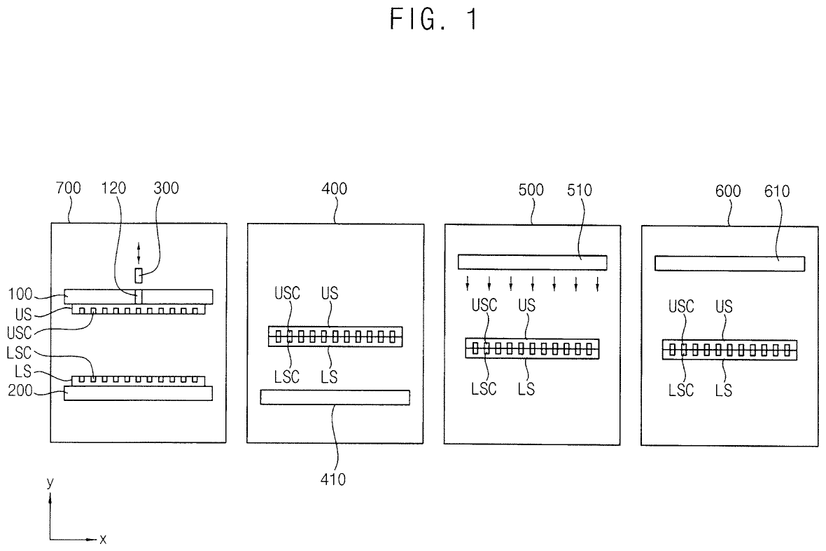

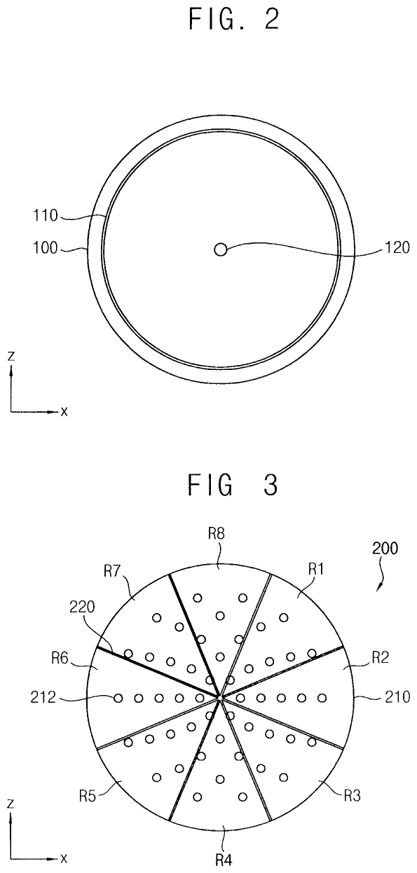

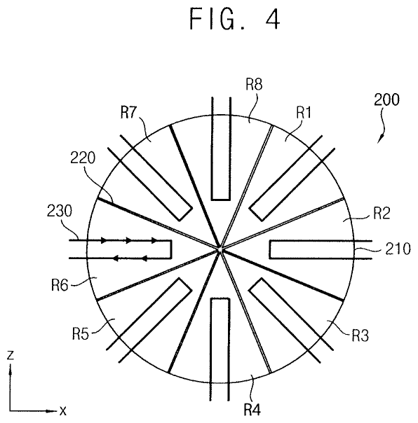

FIG. 1 is a cross-sectional view illustrating an apparatus for bonding substrates in accordance with example embodiments, FIG. 2 is a bottom view illustrating an upper vacuum chuck of the apparatus in FIG. 1, FIG. 3 is a plan view illustrating a lower vacuum chuck of the apparatus in FIG. 1, and FIG. 4 is a cross-sectional view illustrating the lower vacuum chuck in FIG. 3.

Referring to FIG. 1, a bonding apparatus of this example embodiment may bond an upper substrate US and a lower substrate LS with each other. For example, each of the upper substrate US and the lower substrate LS may include a semiconductor substrate. In another example, each of the upper substrate US and the lower substrate LS may include a glass substrate.

A plurality of upper contacts USC may be formed in the upper substrate US. Each of the upper contacts USC may be electrically connected with a corresponding semiconductor chip in the upper substrate US. The upper contacts USC may be exposed through a lower surface of the upper substrate US.

A plurality of lower contacts LSC may be formed in the lower substrate LS. Each of the lower contacts LSC may be electrically connected with a corresponding semiconductor chip in the lower substrate LS. The lower contacts LSC may be exposed through an upper surface of the lower substrate LS.

The bonding apparatus may bond the lower surface of the upper substrate US with the upper surface of the lower substrate LS to electrically connect the upper contacts USC with the lower contacts LSC. The semiconductor chips in the upper substrate US and the lower substrate LS may be electrically connected with each other by electrically connecting the upper contacts USC and the lower contacts LSC with each other. Thus, a bonding fail between the upper substrate US and the lower substrate LS may be determined in accordance with electrical contacts between the upper contacts USC and the lower contacts LSC.

The bonding apparatus may include a bonding unit 700, a grinding unit 400, an annealing unit 500, and an overlay measuring unit 600. For example, referring to FIG. 1, the upper and lower substrates US and LS may be moved through the bonding unit 700, grinding unit 400, annealing unit 500, and overlay measuring unit 600 to complete the bonding between the upper and lower substrates US and LS, e.g., the overlay measuring unit 600 may be used at the end of the process or after each one of the other units.

As illustrated in FIG. 1, the bonding unit 700 may include an upper vacuum chuck 100, a lower vacuum chuck 200, and a bonding pin 300. The bonding pin 300 may push the upper vacuum chuck 100 with the upper substrate US toward the lower vacuum chuck 200 with the lower substrate LS to bond contacts therebetween.

In detail, referring to FIG. 2, the upper vacuum chuck 100 may hold the upper substrate US using vacuum. The upper vacuum chuck 100 may include an upper vacuum hole 110 through which the vacuum may be introduced. The upper vacuum hole 110 may be exposed through a lower surface of the upper vacuum chuck 100 to provide the upper surface of the upper substrate US with the vacuum. In example embodiments, the upper vacuum hole 110 may be arranged at an edge portion of the upper vacuum chuck 100, e.g., the upper vacuum hole 110 may include multiple slits or a single continuous slit along the edge of the upper vacuum chuck 100 (FIG. 2). Thus, the upper vacuum chuck 100 may fix, e.g., only, an edge portion of the upper substrate US. In contrast, a central portion of the upper substrate US, to which the vacuum may not be applied, may not be fixed by the upper vacuum chuck 100.

Referring again to FIG. 1, the bonding pin 300 may be arranged over the upper vacuum chuck 100. The bonding pin 300 may be downwardly moved toward the upper vacuum chuck 100 to pressurize, e.g., push, the upper substrate US toward the lower substrate LS, e.g., along the y axis. A passageway 120 may be formed through a central portion of the upper vacuum chuck 100. The bonding pin 300 may pass through the passageway 120. The bonding pin 300 may be downwardly and upwardly moved by an actuator.

Since the upper vacuum chuck 100 may fix, e.g., only, the edge portion of the upper substrate US, the central portion of the upper substrate US pressurized by the bonding pin 300 may be bent downwardly, e.g., the central portion of the upper substrate US may be pushed farther from the lower surface of the upper vacuum chuck 100 than the edge portion thereof. Thus, a local deformation may be generated in the upper substrate US by the bonding pin 300, which in turn, may cause misalignment between the upper and lower contact USC and LSC.

As illustrated in FIG. 1, the lower vacuum chuck 200 may be arranged under the upper vacuum chuck 100. The lower vacuum chuck 200 may hold the lower substrate LS using vacuum.

Referring to FIGS. 3 and 4, the lower vacuum chuck 200 may include a chucking plate 210, a plurality of partitions 220, and a plurality of temperature control members 230. It is noted that FIGS. 3-4 illustrate a view of a same plane, while FIG. 4 is a cross-section through a thickness (i.e., along a different height along the y axis relative to FIG. 3) of the chucking plate 210 in parallel to the lower substrate LS.

As illustrated in FIGS. 3-4, the chucking plate 210 may include a plurality of lower vacuum holes 212 through which the vacuum may be introduced to the lower surface of the lower substrate LS, e.g., the chucking plate 210 may be formed of metal. The lower vacuum holes 212 may penetrate through the entire chucking plate 210, and may be exposed through an upper surface of the chucking plate 210. The lower vacuum holes 212 may be arranged by a uniform gap to provide the entire lower surface of the lower substrate LS with uniform vacuum. That is, the entire lower surface of the lower substrate LS may closely, e.g., directly, make contact with the upper surface of the chucking plate 210. In example embodiments, the lower vacuum holes 212 may be concentrically arranged in the chucking plate 210.

The partitions 220 may be arranged in the chucking plate 210 to divide the chucking plate 210 into a plurality of regions. For example, as illustrated in FIGS. 3-4, the partitions 220 may penetrate through, e.g., the entire thickness in the y axis of, the chucking plate 210. Temperatures in the regions of the chucking plate 210 divided by the partitions 220 may be independently controlled by the temperature control members 230.

In example embodiments, as illustrated in FIG. 3, the partitions 220 may be radially extended from a center point of the chucking plate 210, e.g., in the xz plane. The partitions 220 may be arranged by substantially the same, e.g., uniform, angle, e.g., relative to the center point of the chucking plate 210. For example, the partitions 220 may be arranged to have eight equally sized partitions around the center point of the chucking plate 210. Thus, the eight partitions 220 may divide the chucking plate 210 into eight, e.g., equal, regions R1, R2, R3, R4, R5, R6, R7, and R8 having substantially the same arc shape. However, the numbers of the partitions 220 may not be restricted within a specific number. Further, the angles between the partitions 220 may be different from each other.

The eight regions R1, R2, R3, R4, R5, R6, R7, and R8 divided by the partitions 220 may be effectively applied to a silicon substrate having (100) crystalline plane. The silicon substrate having the (100) crystalline plane may have different thermal expansion coefficients in the <110> direction, <010> direction, and <100> direction. Because the partitions 220 may be extended in the <110> direction, the <010> direction, and the <100> direction, the temperatures of the eight regions R1, R2, R3, R4, R5, R6, R7, and R8 may be independently controlled in the <110> direction, the <010> direction, and the <100> direction of the silicon substrate.

For example, the partitions 220 may include an adiabatic material for blocking heat exchanges between the adjacent regions R1, R2, R3, R4, R5, R6, R7, and R8. The adiabatic material may not be restricted within a specific material. In another example, the partitions 220 may include an insulating material used in semiconductor fabrication processes.

The temperature control members 230 may be arranged in the regions R1, R2, R3, R4, R5, R6, R7, and R8 of the chucking plate 210, e.g., one temperature control member 230 may be positioned in each one of the regions R1, R2, R3, R4, R5, R6, R7, and R8. The temperature control members 230 may independently control the temperatures of the regions R1, R2, R3, R4, R5 R6, R7, and R8 in the chucking plate 210, e.g., so adjacent regions of the regions R1 through R8 may have different temperatures from each other.

In example embodiments, the temperature control member 230 may include a heat pipe. For example, referring to FIG. 4, the temperature control member 230 may include a U-shaped heat pipe in each region among the regions R1, R2, R3, R4, R5, R6, R7, and R8, where fluid may enter a first end of the U shape, flows through the U shape, and may exit a second end of the U shape (e.g., arrows indicating flow in the heat pipe of the temperature control member 230 of region R6 in FIG. 6). For example, as illustrated in FIG. 4, the heat pipe of the temperature control member 230 may extend radially from an outer edge of the chucking plate 210 toward a center of the chucking plate 210, e.g., both the first and second ends of the U-shaped heat pipe may be external to the chucking plate 210 with the center of the U shape facing the center of the chucking plate 210. For example, the heat pipe of the temperature control member 230 may be embedded within the chucking plate 210.

The heat pipe of the temperature control member 230 may cool a region among the regions R1, R2, R3, R4, R5, R6, R7, and R8 by transferring heat away from the region among the regions R1, R2, R3, R4, R5, R6, R7, and R8 by vaporizing a working fluid. The heat generated by a heat generating portion of the heat pipe may be transferred through a heat dissipation plate so that the heat pipe may have an effective cooling capacity.

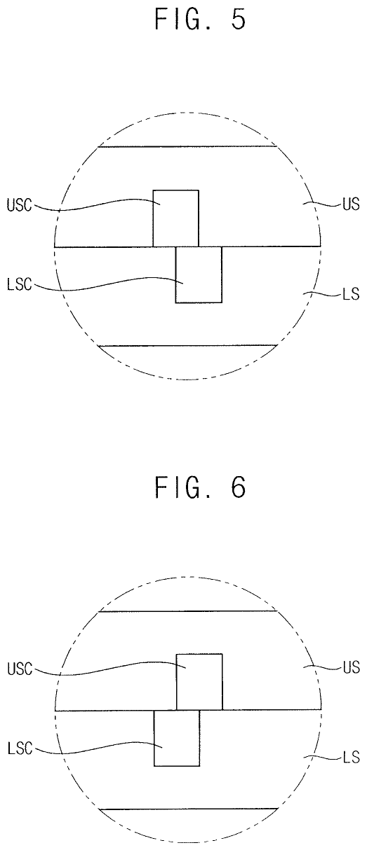

For example, as shown in FIG. 5, when the upper contact USC of the upper substrate US is positioned to the left relative to the lower contact LSC of the lower substrate LS due to a local deformation of the upper substrate US and/or the lower substrate LS after bonding the upper substrate US and the lower substrate LS, the heat pipe of the temperature control member 230 in a region among the regions R1, R2, R3, R4, R5, R6, R7, and R8 of a following lower substrate LS making contact with the lower contact LSC may cool the region before a following, e.g., subsequent, bonding process. The cooled region may contract the portion of the lower substrate LS along the radial direction so that the lower contact LSC may be moved left. Thus, the lower contact LSC may be moved left toward the upper contact USC so that the lower contact LSC may be positioned under the upper contact USC, e.g., so the upper and lower contacts USC and LSC may be properly aligned, in a following, e.g., subsequent, bonding process. As a result, the upper contact USC and the lower contact LSC may be accurately connected with each other.

In another example, as shown in FIG. 6, when the upper contact USC is positioned to the right of the lower contact LSC due to a local deformation of the upper substrate US and/or the lower substrate LS after bonding the upper substrate US and the lower substrate LS, the heat pipe of the temperature control member 230 in a region among the regions R1, R2, R3, R4, R5, R6, R7, and R8 of a following lower substrate LS making contact with the lower contact LSC may heat the region before a following bonding process. The heated region may expand the portion of the lower substrate LS along the radial direction so that the lower contact LSC may be moved right. Thus, the lower contact LSC may be moved right toward the upper contact USC so that the lower contact LSC may be positioned under the upper contact USC, e.g., so the upper and lower contacts USC and LSC may be properly aligned, in a following bonding process. As a result, the upper contact USC and the lower contact LSC may be accurately connected with each other.

Therefore, the upper contacts USC and the lower contacts LSC may be accurately aligned with each other by the independent temperature control of the heat pipe of the temperature control member 230 by the regions R1, R2, R3, R4, R5, R6, R7, and R8. As a result, an accurate connection between the upper contacts USC and the lower contacts LSC may be ensured.

Referring back to FIG. 1, the grinding unit 400 may partially remove the backside of the upper substrate US and/or the lower substrate LS after connecting the upper substrate US with the lower substrate LS, e.g., separate between each of the upper substrate US and the lower substrate LS and its corresponding vacuum chuck. The grinding unit 400 may include a grinder 410 configured to partially remove the backside of the upper substrate US and/or the lower substrate LS. Thus, a thickness of the bonded upper and lower substrates US and LS may be decreased by the grinding unit 400. The grinding process performed by the grinding unit 400 may cause the deformation of the upper and lower substrates US and LS.

The annealing unit 500 may anneal the connected upper and lower substrates US and LS, after performance of the grinding process by the grinding unit 400. The annealing unit 500 may include a heater 510 for heating the upper and lower substrates US and LS. The upper and lower substrates US and LS heated by the heater 510 may be slowly cooled to reinforce a bonding strength between the upper substrate US and the lower substrate LS. The annealing process performed by the annealing unit 500 may cause the deformation of the upper and lower substrates US and LS.

The overlay measuring unit 600 may measure overlays between the upper and lower substrates US and LS on which the bonding process, the grinding process, and the annealing process were performed. That is, the overlay measuring unit 600 may measure the overlays between the upper contacts USC of the upper substrate US and the lower contacts LSC of the lower substrate LS. The overlay measuring unit 600 may include a position sensor 610 for measuring a relative position difference between the upper contact USC and the lower contact LSC.

The overlays between the upper contacts USC and the lower contacts LSC measured by the overlay measuring unit 600 may be applied to a following, e.g., subsequent, bonding process of the following, e.g., next, upper and lower substrates US and LS. In detail, the heat pipes of the temperature control members 230 may selectively control the temperatures of the regions R1, R2, R3, R4, R5, R6, R7, and R8 in the chucking plate 210. Because the regions R1, R2, R3, R4, R5, R6, R7, and R8 of the following lower substrate LS may be selectively heated or cooled by the heat pipes of the temperature control members 230, the following lower substrate LS may be locally expanded or contracted before the following bonding process. Thus, after performing, e.g., each of, the bonding process, the grinding process, and the annealing process on the following upper and lower substrates US and LS, the upper contacts USC of the following upper substrate US and the lower contacts LSC of the following lower substrate LS may be accurately aligned with each other. As a result, the upper contacts USC of the following upper substrate US and the lower contacts LSC of the following lower substrate LS may be accurately connected with each other.

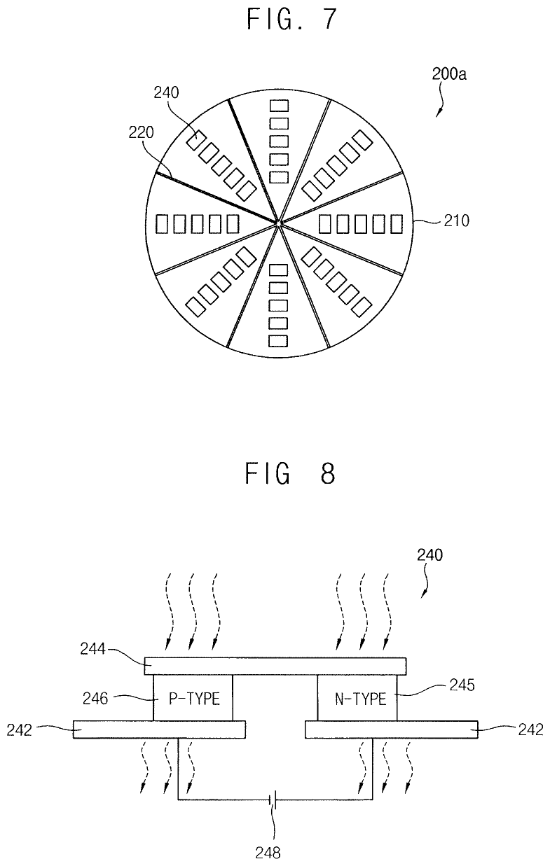

FIG. 7 is a cross-sectional view illustrating a lower vacuum chuck of a bonding apparatus in accordance with example embodiments, and FIG. 8 is a block diagram illustrating a Peltier element of the vacuum chuck in FIG. 7.

A bonding apparatus of this example embodiment may include elements substantially the same as those of the bonding apparatus in FIG. 1, except for a temperature control member of a lower vacuum chuck. Thus, the same reference numerals may refer to the same elements and any further illustrations with respect to the same elements may be omitted herein for brevity.

Referring to FIGS. 7 and 8, a temperature control member 240 of a lower vacuum chuck 200a may include a Peltier element. The Peltier element may be arranged in each of the regions R1 R2, R3, R4, R5, R6, R7, and R8 of the chucking plate 210.

Referring to FIG. 8, the Peltier element of the temperature control member 240 may include first and second heat-emitting plates 242, a heat-absorbing plate 244 opposite to the first and second heat-emitting plates 242, and N type and P type semiconductor devices 245 and 246 interposed between the heat-absorbing plate 244 and the first and second heat-emitting plates 242, respectively. A power supply 248, e.g., a battery, may be electrically connected to the first and second heat-emitting plates 242.

A current may be provided to the first heat-emitting plate 242 from the power supply 248. The current may flow to the second heat-emitting plate 242 through the N type semiconductor device 245, the heat-absorbing plate 244 and the P type semiconductor device 246. Thus, the first and second heat-emitting plates 242 may emit heat. The heat-absorbing plate 244 may absorb heat. This is due to the Peltier effect.

The Peltier effect may be explained as a principle that an ideal gas is cooled down by a constant entropy expansion. When an electron moves from a semiconductor having a high electron concentration to a semiconductor having a low electron concentration, an electron gas may expand and then work with respect to a potential barrier between two plates having a substantially same chemical potential, thereby electrically cooling down an object. The object may be cooled down at a temperature of about 195° F. using the Peltier effect.

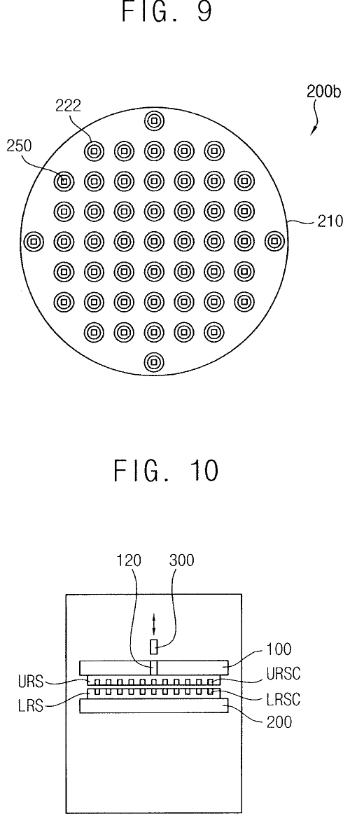

FIG. 9 is a cross-sectional view illustrating a lower vacuum chuck of a bonding apparatus in accordance with example embodiments.

A bonding apparatus of this example embodiment may include elements substantially the same as those of the bonding apparatus in FIG. 1, except for a lower vacuum chuck. Thus, the same reference numerals may refer to the same elements and any further illustrations with respect to the same elements may be omitted herein for brevity.

Referring to FIG. 9, a lower vacuum chuck 200b may include the chucking plate 210, a plurality of partitions 222, and temperature control members 250. The chucking plate 210 may have a structure substantially the same as that in FIG. 1. Thus, any further illustrations with respect to the chucking plate 210 may be omitted herein for brevity.

The partitions 222 may be arranged in the chucking plate 210. Each of the partitions 222 may have an annular shape. The annular partitions 222 may be arranged by a uniform, e.g., constant, gap. Thus, the chucking plate 210 may be divided into a plurality of circular regions by the annular partitions 222. The annular partitions 222 may include an adiabatic material.

Positions of the annular partitions 222 may correspond to the lower contacts LSC of the lower substrate LS. When the lower substrate LS are arranged on the upper surface of the lower vacuum chuck 200b, each of the annular partitions 222 may surround each of the lower contacts LSC.

The temperature control members 250 may be arranged in the circular regions of the chucking plate 210 divided by the annular partitions 222. The temperature control member 250 may include the heat pipe in FIG. 4 or the Peltier element in FIG. 7. Therefore, any further illustrations with respect to the temperature control member 250 may be omitted herein for brevity.

Method of Bonding Substrates

FIGS. 10 to 19 are cross-sectional views illustrating stages in a method of bonding substrates using the apparatus in FIG. 1.

Referring to FIG. 10, the upper vacuum chuck 100 may hold an upper reference substrate URS. The lower vacuum chuck 200 may hold a lower reference substrate LRS. The upper reference substrate URS may include upper reference contacts URSC having an arrangement substantially the same as that of the upper contacts USC of the upper substrate US. The lower reference substrate LRS may include lower reference contacts LRSC having an arrangement substantially the same as that of the lower contacts LSC of the lower substrate LS. For example, the upper and lower vacuum chucks 100 and 200 may be arranged in parallel with each other with the upper and lower reference substrates URS and LRS therebetween, such that the upper and lower reference contacts URSC and LRSC may be aligned and may face each other.

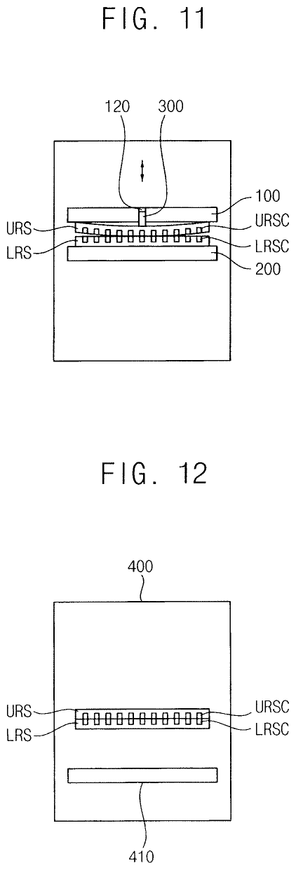

Referring to FIG. 11, the bonding pin 300 may pressurize the upper reference substrate URS toward the lower reference substrate LRS to bond the upper reference substrate URS with the lower reference substrate LRS. A deformation may be generated in the upper reference substrate URS due to the pressure of the bonding pin 300.

Referring to FIG. 12, the bonded upper and lower reference substrates URS and LRS may be transferred to the grinding unit 400. The grinding unit 400 may partially remove a backside of the upper reference substrate URS and/or the lower reference substrate LRS. An additional deformation may be generated in the bonded upper and lower reference substrates URS and LRS due to the grinding process performed by the grinding unit 400.

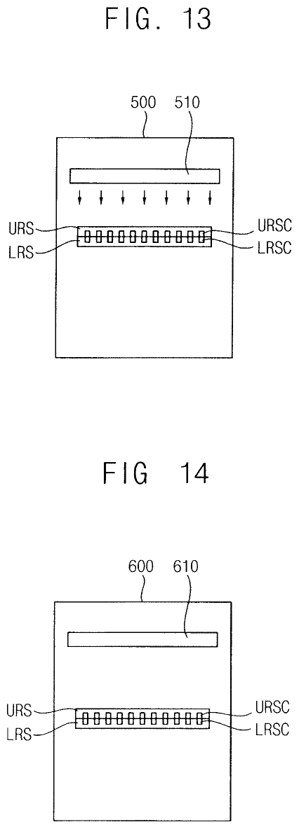

Referring to FIG. 13, after the grinding process, the bonded upper and lower reference substrates URS and LRS may be transferred to the annealing unit 500. The annealing unit 500 may perform the annealing process on the upper and lower reference substrates URS and LRS. An additional deformation may be generated in the upper and lower reference substrates URS and LRS due to the annealing process performed by the annealing unit 500.

Referring to FIG. 14, the annealed upper and lower reference substrates URS and LRS may be transferred to the overlay measuring unit 600. The overlay measuring unit 600 may measure reference overlays between the bonded upper and lower reference substrates URS and LRS. Particularly, the overlay measuring unit 600 may measure horizontal distances between the upper reference contacts URSC and the lower reference contacts LRSC.

Any one among the measured horizontal distances between the upper reference contacts URSC and the lower reference contacts LRSC may be beyond an allowable range. The allowable range may correspond to a horizontal distance for allowing a contact between the upper reference contact URSC and the lower reference contact LRSC. The reference overlays may be reflected on the bonding process of the upper and lower substrates US and LS.

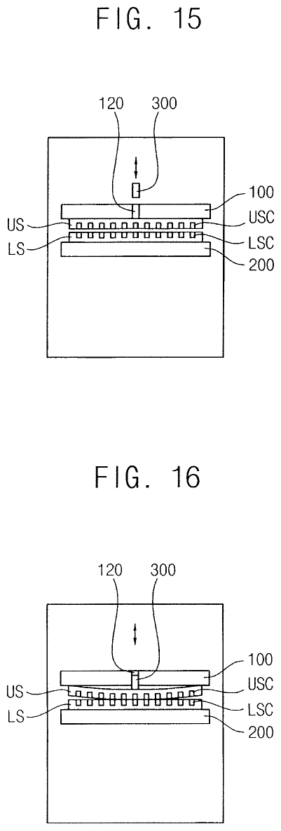

Referring to FIG. 15, the upper vacuum chuck 100 may hold the upper substrate US. The lower vacuum chuck 200 may hold the lower substrate LS. When the reference overlay may be within the allowable range, the temperature control member in a corresponding region may not be operated. In contrast, when the reference overlay may be beyond, e.g., outside, the allowable range, the temperature control member in the corresponding region within the chucking plate of the lower vacuum chuck 200 may heat or cool the corresponding region of the chucking plate 210 to adjust the horizontal distance between the upper and lower reference contacts URSC and LRSC. Thus, a portion of the lower reference substrate LRS making contact with the heated or cooled region may be expanded or contracted, as discussed previously with reference to FIGS. 5-6.

For example, as shown in FIG. 5, when the upper contact USC may be positioned to the left of the lower contact LSC beyond the allowable range, after annealing the upper and lower reference substrates URS and LRS, the temperature control member in the corresponding region may cool the corresponding region of the chucking plate 210. The cooled region may contract the portion of the lower substrate LS along the radial direction so that the lower contact LSC may be moved left by the measured reference overlay.

In another example, as shown in FIG. 6, when the upper contact USC is positioned to the right of the lower contact LSC beyond the allowable range after annealing the upper and lower reference substrates URS and LRS, the temperature control member in the corresponding region may heat the corresponding region of the chucking plate 210. The heated region may expand the portion of the lower substrate LS along the radial direction so that the lower contact LSC may be moved right by the measured reference overlay.

The upper and lower reference contacts URSC and LRSC may be measured in the same way as those of the upper and lower reference substrates URS and LRS described with reference to FIGS. 5-6. Therefore, the reference overlays measured using the upper and lower reference substrates URS and LRS may be measured and previously reflected before bonding the upper and lower substrates US and LS, so that the positions of the lower contacts LSC of the lower substrate LS may be moved in accordance with the previously measured reference overlays.

Referring to FIG. 16, the bonding pin 300 may pressurize the upper substrate US toward the lower substrate LS to bond the upper substrate US with the lower substrate LS. The pressure of the bonding pin 300 applied to the upper and lower substrates US and LS may be substantially the same as the pressure of the bonding pin 300 applied to the upper and lower reference substrates URS and LRS. Thus, a deformation substantially the same as that generated in the upper reference substrate URS by the bonding pin 300 may be generated in the upper substrate US.

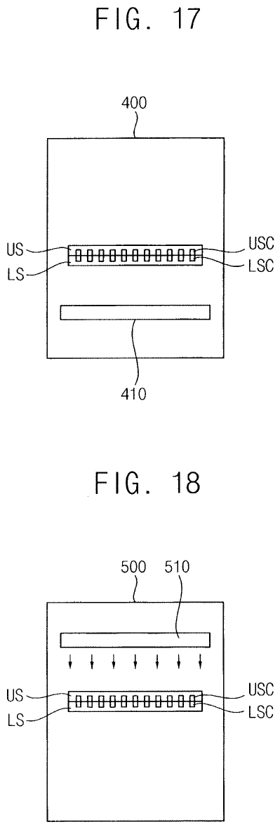

Referring to FIG. 17, the bonded upper and lower substrates US and LS may be transferred to the grinding unit 400. The grinding unit 400 may partially remove the backside of the upper substrate US and/or the lower substrate LS. The deformations of the upper and lower substrates US and LS by the grinding unit 400 may be substantially the same as the deformations of the upper and lower reference substrates URS and LRS by the grinding unit 400.

Referring to FIG. 18, the grinded upper and lower substrates US and LS may be transferred to the annealing unit 500. The annealing unit 500 may perform the annealing process on the upper and lower substrates US and LS. The deformations of the upper and lower substrates US and LS by the annealing unit 500 may be substantially the same as the deformations of the upper and lower reference substrates URS and LRS by the annealing unit 500.

The three deformations generated in the upper and lower substrates US and LS may be reflected on the lower substrate LS by the operations of the temperature control members before bonding the upper and lower substrates US and LS with each other. Thus, the lower contacts LSC may be accurately positioned under the upper contacts USC by the three deformations of the upper and lower substrates US and LS. As a result, the upper and lower contacts USC and LSC may be accurately connected with each other after the annealing process.

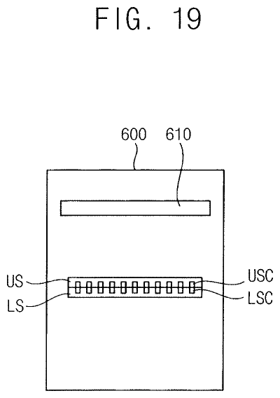

Additionally, referring to FIG. 19, in order to check the accurate connections between the upper and lower contacts USC and LSC, the annealed upper and lower substrates US and LS may be transferred to the overlay measuring unit 600. The overlay measuring unit 600 may measure overlays between the bonded upper and lower substrates US and LS.

By way of summation and review, when upper and lower semiconductor substrates may be bonded with each other, deformations may be generated in the upper and lower semiconductor substrates. Further, after bonding the upper and lower semiconductor substrates with each other, a grinding process may be performed to partially remove a backside of the lower semiconductor substrate and an annealing process may be performed on the bonded upper and lower semiconductor substrates, which may cause additional deformations, thereby causing potential disconnections between contacts in the upper and lower semiconductor substrates.

In contrast, example embodiments provide a vacuum chuck for bonding substrates that is capable of ensuring an accurate connection between contacts by correcting deformations of the substrates. Example embodiments also provide an apparatus for bonding substrates including the above-mentioned vacuum chuck. Example embodiments still also provide a method of bonding substrates using the above-mentioned vacuum chuck.

That is, according to example embodiments, temperature control members may be provided in regions of a chucking plate, e.g., of a lower vacuum chuck, in order to independently heat or cool the regions in accordance with reference overlays, e.g., in accordance with the crystal direction of the wafer. Thus, portions of the substrate making contact with the regions may be selectively expanded or contracted, e.g., with thermal expansion (or contraction) amount being controlled according to the crystal direction of the wafer, to correct deformations, e.g., warpage or distortion, of the substrate. As a result, the contacts may be accurately connected with each other.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A vacuum chuck for bonding substrates, the vacuum chuck comprising:
a chucking plate including vacuum holes to hold a substrate;
partitions arranged in the chucking plate, the partitions dividing the chucking plate into regions; and
a temperature control member in each one of the regions, the temperature control member to independently control temperature in each of the regions to selectively expand or contract portions of the substrate in contact with each of the regions.

2. The vacuum chuck as claimed in claim 1, wherein the partitions are radially extended from a center point of the chucking plate.

3. The vacuum chuck as claimed in claim 2, wherein the partitions are spaced apart from each other by a uniform angle.

4. The vacuum chuck as claimed in claim 2, wherein the temperature control member extends in parallel to a bottom of the chucking plate and in a radial direction relative to the center point of the chucking plate.

5. The vacuum chuck as claimed in claim 1, wherein the partitions include an adiabatic material.

6. The vacuum chuck as claimed in claim 1, wherein the temperature control member includes a heat pipe in each one of the regions.

7. The vacuum chuck as claimed in claim 1, wherein the temperature control member includes a Peltier element in each of the regions.

8. An apparatus for bonding substrates, the apparatus comprising:
an upper vacuum chuck including an upper vacuum hole to hold an upper substrate;
a lower vacuum chuck including:
a chucking plate arranged under the upper vacuum chuck and having vacuum holes to hold a lower substrate,
partitions arranged in the chucking plate, the partitions dividing the chucking plate into regions, and
a temperature control member in each one of the regions, the temperature control member to independently control temperature in each of the regions to selectively expand or contract portions of the lower substrate in contact with each of the regions; and
a bonding pin arranged over the upper vacuum chuck to pressurize the upper substrate toward the lower substrate.

9. The apparatus as claimed in claim 8, wherein the partitions are radially extended from a center point of the chucking plate, and the partitions are spaced apart from each other by a uniform angle.

10. The apparatus as claimed in claim 8, wherein the partitions include an adiabatic material.

11. The apparatus as claimed in claim 8, wherein the upper vacuum hole is at an edge portion of the upper vacuum chuck.

12. The apparatus as claimed in claim 8, wherein the upper vacuum chuck includes a passageway through which the bonding pin passes.

13. The apparatus as claimed in claim 12, wherein the passageway is through the upper vacuum chuck.

14. The apparatus as claimed in claim 8, further comprising an overlay measuring unit to measure overlays between upper contacts of the upper substrate and lower contacts of the lower substrate.

15. The apparatus as claimed in claim 14, wherein the temperature control member is to independently heat or cool the regions in accordance with the overlays to align the upper contacts with the lower contacts.

16. The apparatus as claimed in claim 8, further comprising a grinding unit to partially remove a backside of the upper substrate and/or the lower substrate.

17. The apparatus as claimed in claim 8, further comprising an annealing unit to anneal the upper and lower substrates.

18. (canceled)

19. A method of bonding substrates, the method comprising:
bonding upper and lower reference substrates with each other using upper and lower vacuum chucks;
measuring reference overlays between upper reference contacts of the upper reference substrate and lower reference contacts of the lower reference substrate;
holding an upper substrate to the upper vacuum chuck;
holding a lower substrate to the lower vacuum chuck;
selectively heating or cooling regions in the lower vacuum chuck in accordance with the reference overlays to selectively expand or contact portions of the lower substrate corresponding to the regions, thereby aligning upper contacts of the upper substrate with lower contacts of the lower substrate with each other; and
bonding the upper and lower substrates with each other.

20. The method as claimed in claim 19, further comprising partially removing a backside of the upper reference substrate and/or the lower reference substrate before measuring the reference overlays.

21. The method as claimed in claim 19, further comprising annealing the bonded upper and lower reference substrates.

22-26. (canceled)
